(19) United States
(12) Patent Application Publication
(10) Pub. No.: US 2009/0205950 A1
(43) Pub. Date: Aug. 20, 2009

(54) FILM DEPOSITION APPARATUS AND FILM DEPOSITION METHOD

(75) Inventor: Takeshi Miyashita, Suwa (JP)

Correspondence Address: HARNESS, DICKEY & PIERCE, P.L.C., P.O. BOX 828, BLOOMFIELD HILLS, MI, 48303, US

(73) Assignee: Seiko Epson Corporation, Tokyo (JP)

(21) Appl. No.: 12/364,545

(22) Filed: Feb. 3, 2009

(30) Foreign Application Priority Data
Feb. 18, 2008 (JP) 2008-035643

(51) Int. Cl. C23C 14/35

(52) U.S. Cl. 204/192.12; 204/298.16; 204/298.11

(57) ABSTRACT

A film deposition apparatus includes: a direct current power source; a metal target coupled to the direct current power source; a dielectric frame arranged to surround a periphery of the metal target; an electrode arranged at a back side of the metal target; and a magnetic field generator arranged at a back side of the metal target as well as of the dielectric frame. In the apparatus, at least part of the magnetic field generator is arranged to follow the dielectric frame, and the film deposition apparatus employs reactive direct current sputtering.

The entire disclosure of Japanese Patent Application No. 2008-035643, filed Feb. 18, 2008 is expressly incorporated by reference herein.

### BACKGROUND

1. Technical Field

The present invention relates to a film deposition apparatus and a film deposition method.

2. Related Art

High-frequency sputtering has been commonly used for film deposition of dielectric such as SiO₂. In recent years however, direct current reactive sputtering (hereafter also referred to as DC reactive sputtering) has been suggested, due to problems such as restriction in the flexibility in a structure of a whole film deposition apparatus system and a problem with a film deposition rate. DC reactive sputtering achieves a high film deposition rate with a simple apparatus since sputtering is carried out by an electric discharge generated from a direct current voltage, using any one of metal and a conductive material as a target. In this method, however, a dielectric thin film (oxidation film) is formed by introducing a gas such as oxygen into a chamber and oxidizing sputter particles in vapor or on a substrate surface, and therefore an oxidation film tends to be formed on the surface of a metal target as well. This results in an abnormal electrical discharge being caused since the oxidation film formed on a target surface outside an erosion area is charged up.

Methods which resolve such problems have been suggested, such as high frequency superposition, pulse superposition, and moving a magnet in order to prevent an abnormal discharge by removing an oxidation film on a target surface. For examples, refer to JP-A-7-34242 and JP-A-7-243039.

However, these methods still do not prevent oxidation film from being formed outside the erosion area, due to the sputter particles reaching side surfaces of a target and under a shielding plate. When employing DC reactive sputtering with opposed targets, in particular, the forming of an oxidation film is eminent on a backing plate under the shielding plate. This method inherits problems such as unstable discharge caused by the abnormal discharge and decrease in a film deposition quality originating from the increase of particles being generated due to the abnormal discharge.

### SUMMARY

An advantage of the invention is to provide a film deposition apparatus and a method of film deposition which allow for improving the stability of an electric discharge in the DC reactive sputtering, as well as reducing defects originating from particle generation.

According to a first aspect of the invention, a film deposition apparatus includes: a direct current power source; a metal target coupled to the direct current power source; a dielectric frame arranged to surround a periphery of the metal target; an electrode arranged at a back side of the metal target; and a magnetic field generator arranged at a back side of the metal target as well as of the dielectric frame. In the apparatus, at least part of the magnetic field generator is arranged to follow the dielectric frame, and the film deposition apparatus employs reactive direct current sputtering.

With this film deposition apparatus, the plasma generation region is formed from the surface of the metal target to over the dielectric frame, making edges of the metal target into erosion areas. This prevents the sputter particles from adhering to the surface or the side surfaces of the metal target. This prevents occurrence of abnormal discharge caused by the forming of an oxidation film, allowing for maintaining a stable electric discharge, thereby reducing particle generation and improving film performance. Moreover, the operation rate of the apparatus improves, thereby increasing productivity.

It is preferable that a thickness of the dielectric frame be set so that dielectric breakdown originating from a charge up on a dielectric during discharge is not induced.

This prevents the dielectric frame from a breaking down from an arc discharge. For instance, the dielectric breakdown originating from the charge up during the discharge does not occur by setting the thickness of the dielectric frame to approximately 1 mm or to the thickness of the metal target.

Moreover, providing the same thickness to the dielectric frame and to the metal target allows the side surfaces of the metal target to be covered by the dielectric frame, thereby ensuring the prevention of the sputter particles adhering to the side surfaces.

It is preferable that the dielectric frame be made of one of metal oxide and metal nitride which contain an identical component as that of the metal target.

For instance, in the case of introducing oxygen so as to deposit an oxidation film on a substrate, a metal oxide is used as the dielectric frame so that the dielectric frame includes the same component as that of the metal target. Similarly, in the case of introducing nitrogen gas so as to deposit a nitride film on a substrate, a metal nitride is used as the dielectric frame so that the dielectric frame includes the same component as that of the metal target. Thus sputtering of the dielectric frame does not almost affect the film deposition.

It is preferable that the film deposition apparatus further includes a shielding plate arranged on the dielectric frame and outside a plasma generation region which is larger than a planar region of the metal target.

This allows for sputtering of at least an entire surface of the metal target, thereby improving the film deposition rate and productivity.

In this case, the metal target may be provided in plurality, and the plurality of metal targets is arranged in opposition to each other with the plasma generation region interposed therebetween.

Using the two metal targets allows for in-line film deposition, and carrying a substrate during the film deposition allows for film deposition on a large-size substrate.

It is preferable that the magnetic field generator be arranged at a backside of each of the plurality of metal targets, and a magnetic field is generated in a direction in which the plurality of metal targets are arranged in opposition to each other with the plasma generation region interposed therebetween.

This allows for trapping the plasma inside a space between the opposing metal targets in a preferable manner, thereby improving the sputtering efficiency.

It is preferable that the magnetic field generator move eccentrically within a plane parallel to the metal target.

At the time of moving the magnetic field generator eccentrically, the magnetic field of the magnetic field generator is moved by making part of the magnetic field generator always overlap with the dielectric frame in plan view. This allows for making at least an entire surface of the metal target and part of the dielectric frame be an erosion area.

According to a second aspect of the invention, a method for depositing a film using the film deposition apparatus includes generating a magnetic field so that the plasma generation region covers the dielectric frame arranged to surround the metal target and the periphery of the metal target.

This film deposition method inhibits the adhering of the sputter particles to the surface and the side surfaces of the metal target, thereby preventing the occurrence of the abnormal discharge caused by the forming of the oxidation film, and thus allowing for maintaining a stable discharge. This reduces particle generation and thus improves precision in the film deposition. Moreover, the operation rate of the apparatus improves, thereby increasing productivity.

It is preferable that a pulsed direct current voltage be applied to the metal target, the pulsed direct current voltage including one of a voltage of 0V, a voltage of about 0V, and a voltage having an inverted phase.

This prevents a thin oxide film formed outside the erosion area from being charged up in a short period of time, thereby allowing for maintaining the more stable discharge

### BRIEF DESCRIPTION OF THE DRAWINGS

The invention will be described with reference to the accompanying drawings, wherein like numbers reference like elements.

FIG. 1 is a schematic overall structural view of a film deposition apparatus according to a first embodiment of the invention.

FIG. 2A is a plan view of a magnet pair, and FIG. 2B is a plan view illustrating a positional relationship between a metal target, a dielectric frame, and a magnet pair.

FIG. 3 is a schematic overall structural view of a film deposition apparatus according to a second embodiment of the invention.

FIG. 4 is a schematic overall structural view of a film deposition apparatus according to a third embodiment of the invention.

FIG. 5 is a schematic overall structural view of a film deposition apparatus according to a fourth embodiment of the invention.

FIG. 6 is a plan view illustrating a magnetic field generator according to the fourth embodiment.

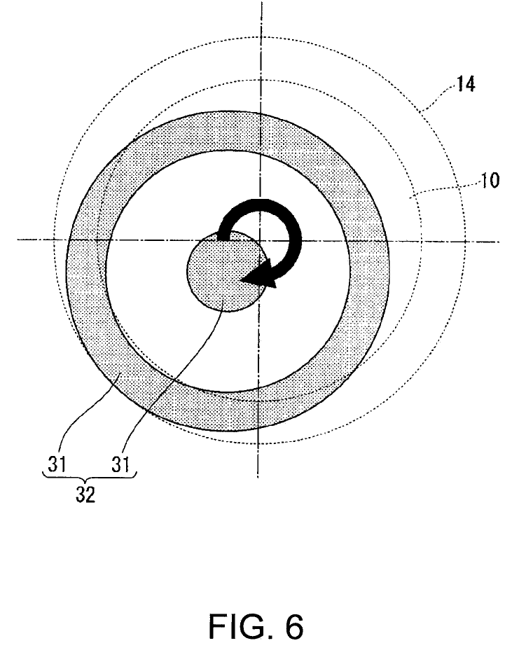

### DESCRIPTION OF EXEMPLARY EMBODIMENTS

Embodiments of the invention will now be described with references to the accompanying drawings. The following figures used in the descriptions below have different scale sizes modified for each of the components, so that each of them will be sufficiently large to be recognized.

### First Embodiment

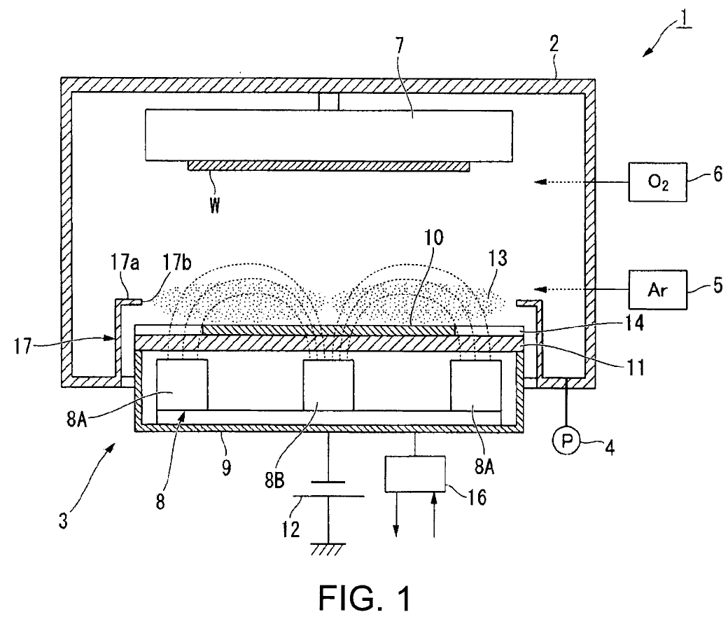

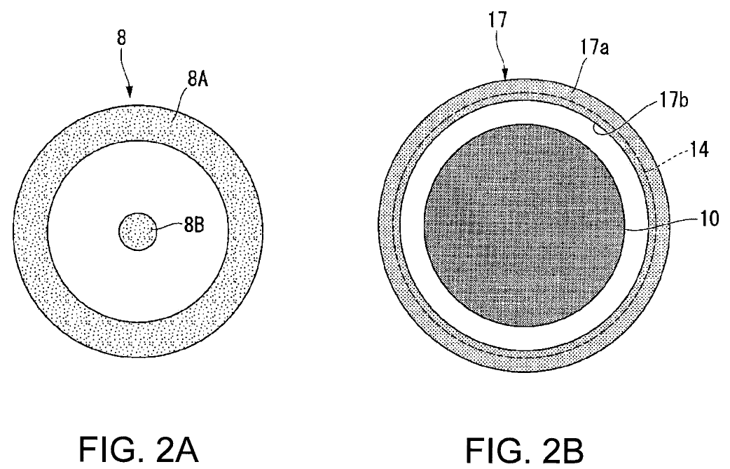

FIG. 1 is a schematic structural view illustrating an example of a film deposition apparatus according to a first embodiment of the invention. FIG. 2A is a plan view of a magnet pair, and FIG. 2B is a plan view illustrating a positional relationship between a metal target, a dielectric frame, and a magnet pair.

As shown in FIG. 1, a film deposition apparatus 1 according to this embodiment uses a reactive DC sputtering method that generates plasma on a metal target 10 arranged inside a vacuumed atmosphere, emits target atoms with the generated plasma, and those emitted particles adhere and deposit on a substrate W that is held on a work holder 7. This film deposition apparatus 1 includes a sputtering apparatus 3 which has main components such as a direct current power source 12 and a magnet pair 8 (magnetic field generator).

DC reactive sputtering is a technique to introduce a reactive gas and oxidize metal particles (sputter particles) in a direct current sputtering condition so as to form a dielectric thin film on the substrate W. This technique achieves a high film deposition rate with a simple apparatus since sputtering is carried out by an electric discharge generated with the direct current power source 12.

The film deposition apparatus according to this embodiment will now be described in detail.

As shown in FIG. 1, the film deposition apparatus 1 according to this embodiment includes: a vacuum chamber 2 that allows for maintaining the vacuum state, serving as a film deposition chamber; and the sputtering apparatus 3 that forms, with a sputtering method, a thin film made of an inorganic material on a surface of the substrate W housed inside the vacuum chamber 2.

The vacuum chamber 2 includes an exhaust system 4 for producing a reduced-pressure atmosphere inside the vacuum chamber 2; a first gas supply unit 5 for supplying sputtering gas for the electric discharge into the vacuum chamber 2 while adjusting the flow rate of the gas; a second gas supply unit 6 for supplying reactive gas into the vacuum chamber 2 while adjusting the flow rate of the reactive gas; and the work holder 7 for holding a substrate inside the vacuum chamber 2.

The exhaust system 4 coupled to the vacuum chamber 2 works to exhaust the interior of the vacuum chamber 2 and produce a vacuum atmosphere. Thereafter, argon gas (Ar) is introduced as the sputtering gas into the vacuum chamber 2 through the first gas supply unit 5, so that the vacuum chamber 2 is set to a prescribed degree of vacuum. The substrate W, a target of sputter film deposition, is arranged within this vacuum atmosphere.

The sputtering apparatus 3 includes an electrode 9 on which the magnet pair 8 is arranged, a backing plate 11 which is supported by the electrode 9 and holds the metal target 10, and the direct current power source 12 coupled to the metal target 10 via the electrode 9. The sputtering apparatus 3 forms a plasma generation region 13 on a surface of the metal target 10 when a voltage is applied.

In this embodiment, a dielectric frame 14 is arranged so as to surround the periphery of the metal target 10 arranged on the backing plate 11.

The electrode 9 is a known magnetron cathode arranged outside the vacuum chamber 2, and receives electricity from the direct current power source 12. The magnet pair 8 that provides a magnetic field on the surface of the metal target 10 is arranged inside the electrode 9, and this magnet pair 8 is made of magnets such as a permanent magnet, an electromagnet, or a magnet combining them. As shown in FIG. 2A, the magnet pair 8 is a concentric permanent magnet, and the polarity of a central magnet 8B is different from that of a ring magnet 8A that surrounds the central magnet 8B.

As shown in FIG. 1, the metal target 10 is arranged on the backing plate 11 supported by the electrode 9, and is made of a material, such as silicon, that includes a constituting substance of the inorganic film formed on the substrate. The direct current power source 12 is coupled to the metal target 10 (electrode 9), and a voltage is applied to the metal target 10 from the direct current power source 12 through the electrode 9, so as to generate plasma on the surface of the metal target 10.

The dielectric frame 14 surrounding the periphery of the metal target 10 is formed with the same material that forms the metal target 10, such as oxide material (SiO₂) or nitride material (SiN). The dielectric frame 14 and the metal target 10 together cover the entire surface of the backing plate 11. The dielectric frame 14 has a prescribed thickness which does not induce an abnormal discharge originating from a charge up of a voltage applied by the direct current power source 12. In this embodiment, it is the same thickness as that of the metal target 10. As a result of providing the same thickness to both the metal target 10 and the dielectric frame 14, the side surfaces of the metal target 10 are covered by the dielectric frame 14.

The dielectric frame 14 may be formed either separately from the backing plate 11 or as an integral unit.

The ring magnet 8A of the magnet pair 8 is arranged at the backside of the dielectric frame 14, so as to follow either an inner or outer peripheral edge of the dielectric frame 14. The magnetic field generated by the magnet pair 8 reaches the dielectric frame 14 by arranging the ring magnet 8A of the magnet pair 8 to be opposed to the dielectric frame 14 with the backing plate 11 interposed therebetween outside the metal target 10 area in plan view. By forming the magnetic field so that the plasma generation region 13 is controlled to cover the dielectric frame 14 as well as the entire surface of the metal target 10, at least the entire surface of the metal target 10 becomes an erosion area.

A cooling unit 16 for cooling down the metal target 10 is coupled to the sputtering apparatus 3, with the backing plate 11 interposed therebetween. A cooling channel (not illustrated) is formed in the backing plate 11 for distributing a cooling medium, and the cooling unit 16 is set to cool down the metal target 10 by circulating the cooling medium in the cooling channel.

A shielding plate 17 is installed inside the vacuum chamber 2 so as to restrict the discharge area of the metal target 10 that serves as a cathode. The shielding plate 17 is grounded near the cathode and is placed around the cathode with a gap smaller than a cathode sheath. The shielding plate 17 is arranged to stand at the bottom of the vacuum chamber 2 so as to surround the outer periphery of the electrode 9 and the dielectric frame 14. A shield 17a positioned above the dielectric frame 14 has an opening 17b which is larger than a planer area of the metal target 10 (refer to FIG. 2B).

### Film Deposition Method

In order to form an inorganic oxide film on the substrate W using the film deposition apparatus 1 with reactive DC sputtering, the interior of the vacuum chamber 2 is exhausted, and argon gas (Ar) for sputtering is optionally introduced from the first gas supply unit 5 positioned in the vicinity of the electrode 9, followed by adjusting the pressure. Thereafter, the direct current power source 12 applies a direct current voltage to the metal target 10, thereby generating plasma on the dielectric frame 14 and on the entire surface of the metal target 10. The introduced argon gas is excited and ionized by the plasma. The metal target 10 and the dielectric frame 14 are sputtered by a substance such as argon ions in the plasma atmosphere. Moreover, the plasma generation region 13 having a high plasma density is generated by the magnetic field of the magnet pair 8, and therefore the collision of argon ions with the metal target 10 increases. As a result, sputter particles scatter from the plasma generation region 13, in other words, this erosion area.

The erosion area in this embodiment is a range including the entire surface of the metal target 10 and part of the surface of the dielectric frame 14. The sputter particles that are flown over a deposition surface of the substrate W react with the oxygen (O₂) introduced from the second gas supply unit 6, and thus form a metal oxide film on the substrate W. In this embodiment, silicon (Si) is used and therefore a SiO₂ inorganic oxide film is formed.

Various metals which combine with oxygen to form a metal oxide film may be used as the metal target 10. Various insulating films can be formed by optionally selecting the reactive gas in addition to selecting the metal target 10. For instance, introducing nitrogen gas allows for forming the metal nitride film on the substrate. The dielectric frame 14 installed in the periphery of the metal target 10 needs to be a metal compound that contains the same element as that of the reactive gas. In the case of using nitrogen gas, metal nitride is used.

This embodiment allows for generating the magnetic field so that the plasma generation region 13 covers the metal target 10 as well as the dielectric frame 14, thereby making at least the entire surface of the metal target 10 into the erosion area. As a result, an oxide film is not formed on the surface of the metal target 10, thereby significantly reducing an occurrence of abnormal discharge. Under the direct current voltage, the dielectric frame 14 is charged up to plasma floating potential when exposed to the plasma generation region 13. However, the bias applied is nominally not strong enough for sputtering. Therefore, the dielectric frame 14 is slightly grinded only by sputtering originating from ion diffusion, which is inconsiderable and does not affect the film deposition. Even if the dielectric frame 14 is sputtered, the sputter particles are the metal oxide containing the same component as that of the metal target 10. Thus there is no effect on the film deposition.

Moreover, since the dielectric frame 14 is made of bulk with a thickness of at least a few millimeters, there is no occurrence of an abnormal discharge originating from the dielectric breakdown, even if the surface of the dielectric frame 14 is charged up by being exposed to plasma. Therefore, installing the dielectric frame 14 cause neither particle generation nor unstable plasma originating from an abnormal discharge. Further, the sputter particles adhere neither to the backing plate 11 nor to the side surfaces of the metal target 10 which are covered by the dielectric frame 14.

Even if the sputter particles reach the lower side of the shielding plate 17 during the reactive sputtering and form an oxide film on the dielectric frame 14 outside the erosion area, this oxide film has high adhesiveness and is less likely to delaminate since it is made of the same material as that of the deposition material.

This prevents the abnormal discharge originating from the forming of the oxidation film on the side surface of the metal target 10 as well as on the backing plate 11, and a stable discharge is maintained. This reduces particle generation and thus improves film performance. Moreover, the operation rate of the apparatus improves, thereby increasing productivity.

### Film Deposition Apparatus in the Second Embodiment

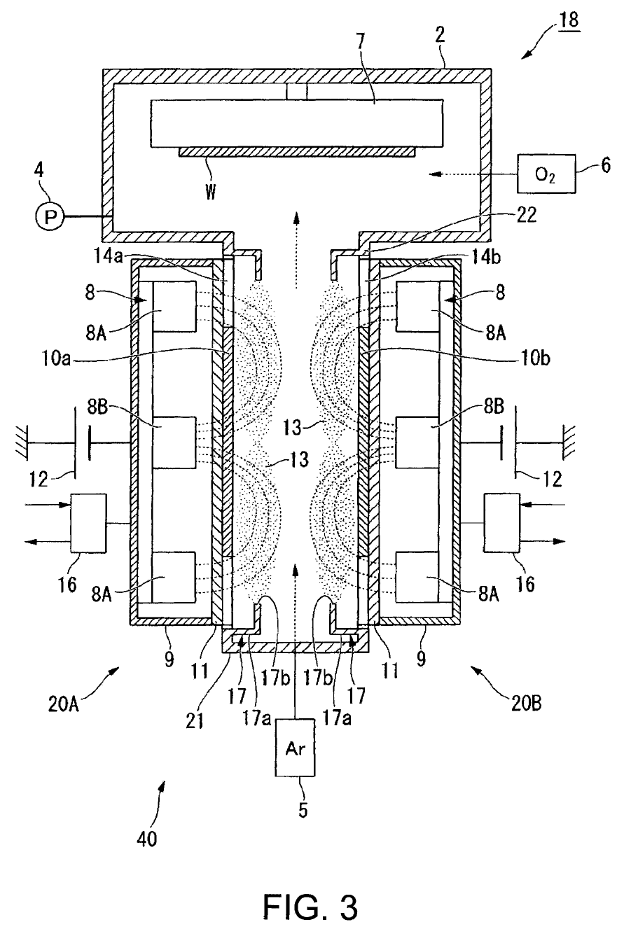

FIG. 3 is a schematic view illustrating a structure of a film deposition apparatus according to a second embodiment of the invention.

In the following description, the same structures and members as that of the first embodiment are denoted by the same numerical symbols, and the detailed descriptions thereof are simplified or omitted.

The film deposition apparatus according to this embodiment uses an opposed target sputtering method in which two metal targets are arranged in opposition to each other.

As shown in FIG. 3, a film deposition apparatus 18 according to this embodiment includes the vacuum chamber 2 that houses the substrate W, and a sputtering apparatus 40 that forms a metal oxide film on a deposition surface of the substrate W inside the vacuum chamber 2. The vacuum chamber 2 and the sputtering apparatus 40 are coupled with a coupling unit 22 interposed therebetween.

The sputtering apparatus 40 includes: a plasma generator 20A that includes a metal target 10a, the magnet pair 8, the electrode 9, the backing plate 11, the direct current power source 12, and the cooling unit 16; and a plasma generator 20B that includes a metal target 10b, the magnet pair 8, the electrode 9, the backing plate 11, the direct current power source 12, and the cooling unit 16. These two metal targets 10a and 10b are held vertically relative to a surface (deposition surface) of the substrate W arranged inside the vacuum chamber 2.

Peripheries of the metal targets 10a and 10b are respectively surrounded by dielectric frames 14a and 14b, and the opposing planes of the metal targets 10a and 10b as well as those of the dielectric frames 14a and 14b are arranged approximately in parallel.

The direct current power source 12 is coupled to each of the metal targets 10a and 10b (each electrode 9). The power supplied from the direct current power source 12 generates plasma in spaces interposed by the metal targets 10a and 10b as well as by the dielectric frames 14a and 14b.

The sputtering apparatus 40 includes the first gas supply unit 5 that distributes argon gas (Ar) for electric discharge in the plasma generation region 13, and is coupled to a sidewall member 21 arranged at a side opposite to the vacuum chamber 2 across the plasma generation region 13 interposed by the metal targets 10a and 10b. The argon gas (Ar) supplied from the first gas supply unit 5 flows into the plasma generation region 13 from the sidewall member 21, and further flows upward into the vacuum chamber 2 through the coupling unit 22. At the same time, the vacuum chamber 2 includes the second gas supply unit 6 that supplies oxygen (O₂) as a reactive gas into the vicinity of the substrate W inside the vacuum chamber 2.

Similar to the first embodiment, the shielding plate 17 is arranged to surround periphery of each of the dielectric frames 14a and 14b, and the edge of the shield 17a is positioned over each of the dielectric frames 14a and 14b. In other words, the opening 17b of the shielding plate 17 is larger than the planer area of each of the metal targets 10a and 10b.

The cooling unit 16 coupled to the electrode 9 in this embodiment also circulates the cooling medium in a cooling channel R formed inside the electrode 9, and cools the metal targets 10a and 10b to a desired temperature through the backing plate 11.

### Film Deposition Method

As shown in FIG. 3, in order to form a metal oxide film on the substrate W with the film deposition apparatus 18, direct current power is supplied to the metal targets 10a and 10b while the first gas supply unit 5 introduces argon (Ar) gas, so as to generate plasma in a space interposed by these two metal targets 10a and 10b. Specifically, magnetic fields are generated so that the plasma generation region 13 covers the entire surfaces of the metal targets 10a and 10b, as well as part of the dielectric frame 14a and of the dielectric frame 14b. Thereafter, the film deposition material (silicon) is knocked out from the metal targets 10a and 10b as the sputter particles by striking the metal targets 10a and 10b with a substance such as argon ions in the plasma atmosphere.

Subsequently to generating plasma by introducing argon gas from the first gas supply unit 5, oxygen gas is introduced into the vacuum chamber 2 from the second gas supply unit 6. A thin film made of a metal oxide is formed on the substrate W by reacting, above the deposition surface of the substrate W, the sputter particles flown from the sputtering apparatus 40 with the oxygen gas supplied from the second gas supply unit 6 provided in the vicinity of the substrate W.

As described, the second embodiment allows for obtaining the similar effect as that of the first embodiment. Using the two metal targets 10a and 10b allows for an in-line film deposition, and carrying a substrate during the film deposition allows for film deposition on a large-size substrate. Moreover, narrowing the space between the metal targets 10a and 10b makes the sputter particles more directional, the sputter particles being emitted in a target direction in which the sputtering apparatus 40 faces through the coupling unit 22, thereby allowing for increasing the film deposition quality of the metal oxide film formed.

### Film Deposition Apparatus in the Third Embodiment

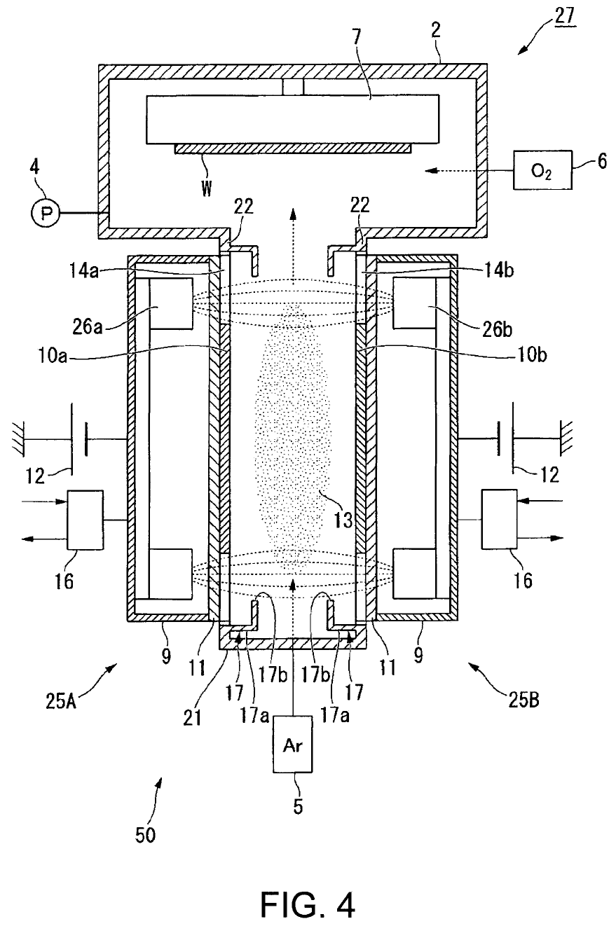

FIG. 4 is a block diagram of a film deposition apparatus according to a third embodiment of the invention.

In the following description, the same structures and members as that of the first embodiment are denoted by the same numerical symbols, and the detailed descriptions thereof are simplified or omitted.

Similar to the second embodiment, the film deposition apparatus according to the third embodiment employs the opposed target sputtering method in which two metal targets are arranged in opposition to each other. However, the structure of the magnetic field generator is different.

As shown in FIG. 4, plasma generators 25A and 25B of a sputtering apparatus 50 include magnetic field generators 26a and 26b each composed with a ring magnet that follows the peripheral edge of the metal target 10a or 10b. The magnetic field generator 26a is arranged at the backside of the dielectric frame 14a, and the magnetic field generator 26b is arranged at the backside of the dielectric frame 14b. In other words, the magnetic field generators 26a and 26b are arranged in opposition to each other, outside the perimeters of the metal targets 10a and 10b arranged in opposition to each other.

Here, the polarities of the magnetic field generators 26a and 26b are different from each other.

At the time of film deposition, magnetic fields that surround the metal targets 10a and 10b are formed by the magnetic field generators 26a and 26b which are in opposition to each other. Such magnetic fields allow a film deposition apparatus 27 according to this embodiment to capture and reflect electrons included in the plasma. Therefore the plasma is trapped inside the space between the opposing metal targets 10a and 10b in a preferable manner.

### Film Deposition Apparatus in the Fourth Embodiment

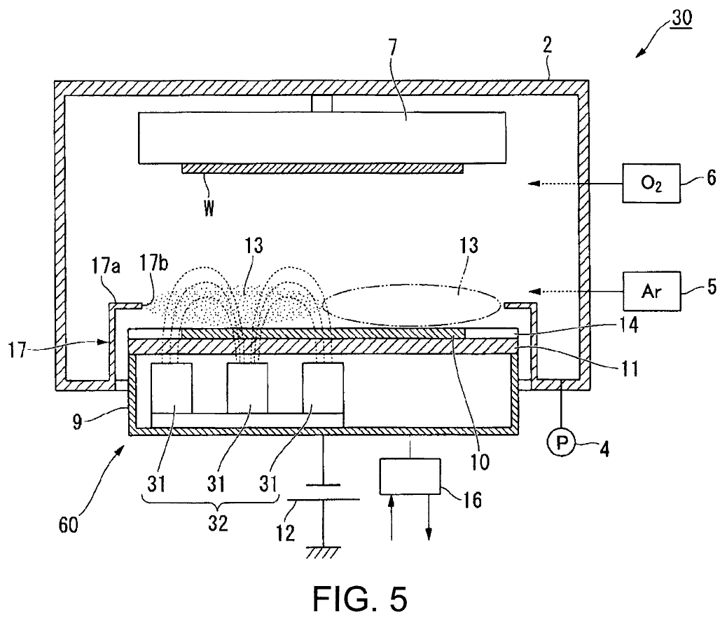

FIG. 5 is a block diagram of a film deposition apparatus according to a fourth embodiment of the invention.

In the following description, the same structures and members as that of the first embodiment are denoted by the same numerical symbols, and the detailed descriptions thereof are simplified or omitted.

As shown in FIG. 5, a film deposition apparatus 30 according to this embodiment employs a magnetic scanning method, and a sputtering apparatus 60 includes a magnetic field generator 32 that has a circular shape in which the north pole and the south pole are arranged concentrically.

The magnetic field generator 32 is arranged away from the center of the electrode 9 (metal target 10), so that at least one of the plurality of magnets 31 which is shaped like a ring is arranged outside the perimeter of the metal target 10, that is to say, at the backside of the dielectric frame 14. This magnetic field generator 32 is formed so that the plurality of magnets 31 moves eccentrically within a plane (direction indicated in an arrow in the drawing) parallel to the metal target 10.

At the time of film deposition, the magnetic field generator 32 is moved eccentrically. Here, the plurality of magnets 31 constitutes the magnetic field generator 32, and is moved eccentrically so that part of one of the magnets 31 which is shaped like a ring always overlaps with the dielectric frame 14 in plan view. The magnetic fields of the magnets 31 are moved by the eccentric movement of the magnets 31 relative to the metal target 10, and therefore at least the entire surface of the metal target 10 and part of the dielectric frame 14 become an erosion area.

The shapes of the magnets 31 are not limited to what is described above, and may include, in addition to a concentric magnet structure, an oblong structure formed with a combination of a plurality of magnets with shapes such as a square.

As described, according to the invention, by forming the magnetic field so that the plasma generation region 13 covers the dielectric frame 14 as well as the entire surface of the metal target 10, at least the entire surface of the metal target 10 becomes an erosion area. This prevents the deposition of sputter particles (oxides) on the surface of the metal target 10. Further, the dielectric frame 14 that surrounds the periphery of the metal target 10 prevents the deposition of sputter particles (oxides) on the backing plate 11 and on the side surfaces of the metal target 10. Providing the dielectric frame 14 that has a prescribed thickness prevents oxides deposited on the area outside the erosion area from being charged up. Moreover, this reduces the deposition of oxides on the metal target 10 and on the backing plate 11, thereby stabilizing the plasma while preventing an abnormal discharge.

Consequently, particles are reduced and the uniformity of film quality improves. Moreover, the film deposition rate increases since the entire surface of the metal target 10 becomes the erosion area.

Further, the invention exhibit effects such as preventing the decline in a film deposition rate by suppressing the deposition of oxide with a low sputtering rate.

While embodiments of the invention have been described with reference to the accompanying drawings, it goes without saying that the invention is not limited thereto, and the above referenced embodiments may be used in combination. It will be apparent that those skilled in art may contemplate other various modifications and adjustments within the scope of the technical spirit described in claims. It is understood that these modifications and adjustments will also naturally be attributed to the technical scope of the invention.

While the shape of the target is circular and the shape of the magnet pair is concentric in the above embodiments, one of the magnet pair may also be shaped like a thin rod, and the surrounding magnet may be a rectangular shape. Moreover, the target may also be square, and the shape of the magnets may conform the shape of the target.

A high frequency power source may also be provided as an alternative to the direct current power source 12. Simultaneously applying a high frequency voltage in addition to the direct current prevents the oxide charge from building up and stabilizes the plasma.

Moreover, a pulsed direct current may be applied between the metal target 10 and the electrode 9. This prevents an oxide film from charging up even if the oxide film may be formed in the area outside the erosion area.

What is claimed is:

1. A film deposition apparatus, comprising:
a direct current power source;
a metal target coupled to the direct current power source;
a dielectric frame arranged to surround a periphery of the metal target;
an electrode arranged at a back side of the metal target; and
a magnetic field generator arranged at a back side of the metal target as well as of the dielectric frame;
wherein at least part of the magnetic field generator is arranged to follow the dielectric frame, and the film deposition apparatus employs reactive direct current sputtering.

2. The film deposition apparatus according to claim 1, wherein a thickness of the dielectric frame is set so that dielectric breakdown originating from a charge up on a dielectric during discharge is not induced.

3. The film deposition apparatus according to claim 1, wherein the dielectric frame is made of one of metal oxide and metal nitride which contain an identical component as that of the metal target.

4. The film deposition apparatus according to claim 1, further comprising a shielding plate arranged on the dielectric frame as well as outside a plasma generation region which is larger than a planar region of the metal target.

5. The film deposition apparatus according to claim 1, wherein:
the metal target is provided in plurality; and
the plurality of metal targets is arranged in opposition to each other with the plasma generation region interposed therebetween.

6. The film deposition apparatus according to claim 5, wherein:
the magnetic field generator is arranged at a backside of each of the plurality of metal targets; and
a magnetic field is generated in a direction in which the plurality of metal targets are arranged in opposition to each other with the plasma generation region interposed therebetween.

7. The film deposition apparatus according to claim 1, wherein the magnetic field generator moves eccentrically within a plane parallel to the metal target.

8. A method for depositing a film using the film deposition apparatus according to claim 1, comprising:
generating a magnetic field so that the plasma generation region covers the dielectric frame arranged to surround the metal target and the periphery of the metal target.

9. The method for depositing a film according to claim 8, wherein a pulsed direct current voltage is applied to the metal target, the pulsed direct current voltage including one of a voltage of 0V, a voltage of about 0V, and a voltage having an inverted phase.
